(19) United States
(12) Patent Application Publication
(10) Pub. No.: US 2026/0344154 A1
(43) Pub. Date: Oct. 29, 2026

(54) LIGHT EMITTING DEVICE AND LIGHT EMITTING SYSTEM

(71) Applicant: SEOUL SEMICONDUCTOR CO., LTD., Ansan-si (KR)

(72) Inventor: ChulHwan KANG, Ansan-si (KR)

(73) Assignee: SEOUL SEMICONDUCTOR CO., LTD., Ansan-si (KR)

(21) Appl. No.: 19/632,766

(22) Filed: Mar. 30, 2026

Related U.S. Application Data
(60) Provisional application No. 63/781,598, filed on Apr. 1, 2025.

(51) Int. Cl. H10H 29/80

(52) U.S. Cl. CPC H10H 29/8321

(57) ABSTRACT

According to an aspect of the present disclosure, there may be provided a light emitting device including: a substrate; a first light emitter disposed on the substrate and configured to generate light; and a second light emitter disposed on the substrate, spaced apart from the first light emitter in a first direction, and configured to generate light, wherein the substrate includes: a first substrate electrode electrically connected to the first light emitter; and a second substrate electrode electrically connected to the second light emitter and spaced apart from the first substrate electrode, wherein one side of the first substrate electrode is disposed to face one side of the second substrate electrode, and wherein at least one of the one side of the first substrate electrode and the one side of the second substrate electrode is disposed between the first light emitter and the second light emitter.

### TECHNICAL FIELD

The present disclosure relates to a light emitting device and a light emitting system including the same.

### BACKGROUND OF INVENTION

Recently, light emitting diodes (LEDs) are widely used. Alight emitting diode converts an electrical signal into a form of light, such as infrared rays, visible light, or ultraviolet rays, by using characteristics of a compound semiconductor.

As the light efficiency of light emitting diodes increases, the light emitting diodes are being applied to various fields including a display device, a lighting device, a vehicle, and an optical communication device.

### Contents of Invention

### Problems to be Solved by Invention

Embodiments of the present disclosure provide a light emitting device and a light emitting system in which a color separation phenomenon is suppressed.

### Means for Solving Problems

In accordance with an aspect of the present disclosure, there may be provided a light emitting device including: a substrate; a first light emitter disposed on the substrate and configured to generate light; and a second light emitter disposed on the substrate to be spaced apart from the first light emitter in one direction and configured to generate light, wherein the substrate includes: a first substrate electrode electrically connected to the first light emitter; and a second substrate electrode electrically connected to the second light emitter and spaced apart from the first substrate electrode, wherein one side of the first substrate electrode is disposed to face one side of the second substrate electrode, and wherein at least one of the one side of the first substrate electrode and the one side of the second substrate electrode is disposed between the first light emitter and the second light emitter.

Further, there may be provided the light emitting device in which a separation distance between the first substrate electrode and the second substrate electrode in the one direction is smaller than a separation distance between the first light emitter and the second light emitter in the one direction.

Further, there may be provided the light emitting device in which the first light emitter includes: a first A-type conductivity-type semiconductor layer; a first active layer stacked on the first A-type conductivity-type semiconductor layer; a first B-type conductivity-type semiconductor layer stacked on the first active layer; and a first light transmitting layer stacked on the first B-type conductivity-type semiconductor layer, wherein the first A-type conductivity-type semiconductor layer is connected to the first substrate electrode, wherein the second light emitter includes: a second A-type conductivity-type semiconductor layer; a second active layer stacked on the second A-type conductivity-type semiconductor layer; a second B-type conductivity-type semiconductor layer stacked on the second active layer; and a second light transmitting layer stacked on the second B-type conductivity-type semiconductor layer, and wherein the second B-type conductivity-type semiconductor layer is connected to the second substrate electrode.

Further, there may be provided the light emitting device in which the substrate further includes: a third substrate electrode electrically connected to the first light emitter and the second light emitter and spaced apart from the first substrate electrode and the second substrate electrode, wherein the first B-type conductivity-type semiconductor layer is connected to the third substrate electrode, and the second A-type conductivity-type semiconductor layer of the second light emitter is connected to the third substrate electrode.

Further, there may be provided the light emitting device in which the first light emitter emits light of a first peak wavelength, the second light emitter emits light of a second peak wavelength, and a difference between the first peak wavelength and the second peak wavelength is 59 nm to 150 nm.

Further, there may be provided the light emitting device in which the first light emitter and the second light emitter are formed such that a length thereof in another direction perpendicular to the one direction is greater than a length thereof in the one direction.

Further, there may be provided the light emitting device in which a sum of a length of the first light emitter in the one direction, a length of the second light emitter in the one direction, and a separation distance between the first light emitter and the second light emitter is larger than a length of the first light emitter in the other direction.

Further, there may be provided the light emitting device in which a length of the first light emitter in the one direction is larger than a separation distance between the first light emitter and the second light emitter.

Further, there may be provided the light emitting device further including: a partition wall disposed on the substrate to provide an accommodation space accommodating the first light emitter and the second light emitter and including a side wall inclined with respect to the substrate.

Further, there may be provided the light emitting device in which one side of the first light emitter is disposed to face the second light emitter, and a separation distance from a center between an end of the first light emitter in another direction perpendicular to the one direction and an end of the second light emitter in the other direction to a lower end of the side wall is larger than a separation distance from a center of the other side opposite to the one side of the first light emitter to the lower end of the side wall.

Further, there may be provided the light emitting device further including: a molding layer disposed in the accommodation space of the partition wall to cover the first light emitter and the second light emitter.

Further, there may be provided the light emitting device in which a phosphor being a wavelength conversion material is provided in the molding layer.

Further, there may be provided the light emitting device in which the substrate further includes: an insulator disposed among the first substrate electrode, the second substrate electrode, and the third substrate electrode.

Further, there may be provided the light emitting device further including: an auxiliary element disposed on the second substrate electrode.

Further, there may be provided a light emitting device including: a substrate; a first light emitter disposed on the substrate and configured to generate light; and a second light emitter disposed on the substrate to be spaced apart from the first light emitter in one direction and configured to generate light, wherein the substrate includes: a first substrate electrode electrically connected to the first light emitter; and a second substrate electrode electrically connected to the second light emitter and spaced apart from the first substrate electrode, and wherein a ratio of a separation distance between the first light emitter and the second light emitter to a thickness of the first light emitter is greater than 0.4 and less than 4.

Further, there may be provided a light emitting device including: a substrate; a first light emitter disposed on the substrate and configured to generate light; and a second light emitter disposed on the substrate to be spaced apart from the first light emitter in one direction and configured to generate light, wherein the substrate includes: a first substrate electrode electrically connected to the first light emitter and the second light emitter; and a second substrate electrode disposed to be spaced apart from the first substrate electrode in another direction perpendicular to the one direction, and electrically connected to the first light emitter and the second light emitter.

Further, there may be provided the light emitting device in which the first light emitter includes: a first A-type conductivity-type semiconductor layer; a first active layer stacked on the first A-type conductivity-type semiconductor layer; a first B-type conductivity-type semiconductor layer stacked on the first active layer; and a first light transmitting layer stacked on the first B-type conductivity-type semiconductor layer, and the second light emitter includes: a second A-type conductivity-type semiconductor layer; a second active layer stacked on the second A-type conductivity-type semiconductor layer; a second B-type conductivity-type semiconductor layer stacked on the second active layer; and a second light transmitting layer stacked on the second B-type conductivity-type semiconductor layer, and the first A-type conductivity-type semiconductor layer is connected to the first substrate electrode, the first B-type conductivity-type semiconductor layer is connected to the second substrate electrode, the second A-type conductivity-type semiconductor layer is connected to the first substrate electrode, and the second B-type conductivity-type semiconductor layer is connected to the second substrate electrode.

Further, there may be provided the light emitting device in which the first substrate electrode includes: a first sub-electrode connected to the first A-type conductivity-type semiconductor layer; and a second sub-electrode disposed to be spaced apart from the first sub-electrode in the one direction, and connected to the second A-type conductivity-type semiconductor layer, and the second substrate electrode includes: a third sub-electrode disposed to be spaced apart from the first sub-electrode in the other direction, and connected to the first B-type conductivity-type semiconductor layer; and a fourth sub-electrode disposed to be spaced apart from the second sub-electrode in the other direction while being disposed to be spaced apart from the third sub-electrode in the one direction, and connected to the second B-type conductivity-type semiconductor layer.

Further, there may be provided the light emitting device in which a separation distance between the first sub-electrode and the second sub-electrode is shorter than a separation distance between the first light emitter and the second light emitter, and a separation distance between the third sub-electrode and the fourth sub-electrode is shorter than the separation distance between the first light emitter and the second light emitter.

Further, there may be provided the light emitting device further including: an auxiliary element disposed on at least one of the third sub-electrode and the fourth sub-electrode.

### Effects of Invention

According to an embodiment of the present disclosure, since the first light emitter and the second light emitter are disposed close to each other, a beam angle of the light emitting device may be formed close to a circular shape, and color separation may be prevented from occurring.

Furthermore, according to an embodiment of the present disclosure, the first light emitter and the second light emitter may be connected in series or in parallel.

Furthermore, according to an embodiment of the present disclosure, when viewed from above, since one side of the first substrate electrode and one side of the second substrate electrode are disposed between the first light emitter and the second light emitter, light generated between the first light emitter and the second light emitter may be mixed while being reflected.

Furthermore, according to an embodiment of the present disclosure, since the first side wall separation distance is larger than the second side wall separation distance, a first space formed by the first side wall separation distance may be larger than a second space formed by the second side wall separation distance.

Furthermore, according to an embodiment of the present disclosure, since light generated between the first light emitter and the second light emitter travels in the other direction and is efficiently mixed in the first space wider than the second space, a color separation phenomenon may be suppressed.

### BRIEF DESCRIPTION OF DRAWINGS

FIG. 1 is a view illustrating a light emitting device according to a first embodiment of the present disclosure.

FIG. 2 is a cross-sectional view illustrating the light emitting device of FIG. 1 taken along A-A′.

FIG. 3 is a view illustrating that an electrode separation distance of the light emitting device according to the first embodiment of the present disclosure is formed to be longer than an element separation distance.

FIG. 4 is a view illustrating a light emitting device according to a second embodiment of the present disclosure.

FIG. 5 is a view illustrating a light emitting device according to a third embodiment of the present disclosure.

FIG. 6 is a view illustrating that a separation distance between a first sub-electrode and a second sub-electrode of the light emitting device according to the third embodiment of the present disclosure is longer than a separation distance between the first light emitter and the second light emitter.

FIG. 7 is a view illustrating a light emitting system according to a first embodiment of the present disclosure.

FIG. 8 is a view illustrating a light emitting system according to a second embodiment of the present disclosure.

FIG. 9 is a view illustrating a light emitting system according to a third embodiment of the present disclosure.

FIG. 10 is a view illustrating a light emitting system according to a fourth embodiment of the present disclosure.

FIG. 11 is a view illustrating a light emitting system according to a fifth embodiment of the present disclosure.

### SPECIFIC CONTENTS FOR EMBODYING INVENTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a light emitting device 1 according to a first embodiment of the present disclosure will be described.

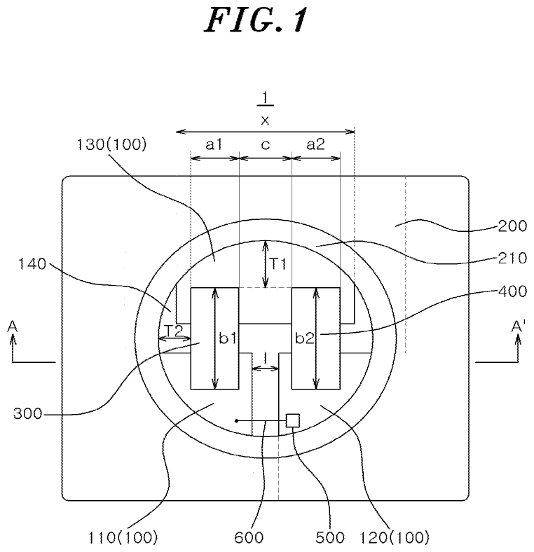

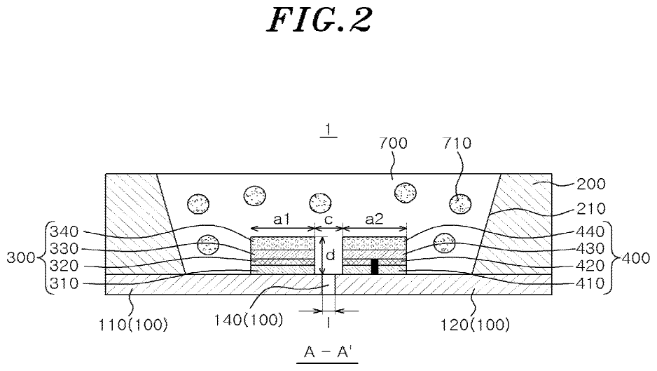

Referring to FIGS. 1 and 2, the light emitting device 1 may receive power from the outside to generate light. For example, the light emitting device 1 may be included in a lighting device, a display device, an optical communication device, or a vehicle lamp. The light emitting device 1 may display a letter, a symbol, or an image. The light emitting device 1 may include a substrate 100, a partition wall 200, a first light emitter 300, and a second light emitter 400. Furthermore, an auxiliary element 500, a conductor 600, and a molding layer 700 may be additionally included.

The partition wall 200, the first light emitter 300, the second light emitter 400, and the molding layer 700 may be disposed on the substrate 100. For example, the substrate 100 may be an electrically conductive substrate. Furthermore, the substrate 100 may be a PCB (printed circuit board) on which an electric circuit is printed. Furthermore, the substrate 100 may be a TFT (thin-film transistor) backplane. Furthermore, the substrate 100 may include at least one of Cu, Zn, Au, Ni, Al, Mg, Cd, Be, W, Mo, Si, Ag, and Fe, or an alloy composed of a portion thereof. However, the present disclosure is not limited thereto, and the substrate 100 may include at least one of FR1, CEM-1, and FR-4. Here, FR1 is a material in which a copper foil and a laminate paper are stacked, and CEM-1 is a material in which a copper foil, a glass fiber fabric, a laminate paper, and a glass fiber fabric are sequentially stacked. Furthermore, FR-4 is a material in which a copper foil and a glass fiber fabric or a glass fiber fabric are stacked. In addition, the substrate 100 may include a ceramic such as alumina (Al₂O₃), aluminum nitride (AlN), or ZTA (Zirconia Toughened Alumina). Furthermore, the substrate 100 may include a first substrate electrode 110, a second substrate electrode 120, and a third substrate electrode 130. Furthermore, an insulator 140 may be disposed among the first substrate electrode 110, the second substrate electrode 120, and the third substrate electrode 130.

The first substrate electrode 110 may include a material having conductivity. The first substrate electrode 110 may be electrically connected to the first light emitter 300. The first substrate electrode 110 may be disposed to be spaced apart from the second substrate electrode 120 and the third substrate electrode 130. Furthermore, the first substrate electrode 110 may be arranged to reflect light upward.

The second substrate electrode 120 may include a material having conductivity. The second substrate electrode 120 may be electrically connected to the second light emitter 400. Furthermore, the second substrate electrode 120 may be disposed to be spaced apart from the first substrate electrode 110 in one direction. The one direction may be a direction in which the first light emitter 300 and the second light emitter 400 are spaced apart. One side of the second substrate electrode 120 and one side of the first substrate electrode 110 may be disposed to face each other. The one side of the second substrate electrode 120 and the one side of the first substrate electrode 110 may be disposed to be spaced apart from each other. Hereinafter, a separation distance between the one side of the second substrate electrode 120 and the one side of the first substrate electrode 110 is referred to as an electrode separation distance 1. Furthermore, the second substrate electrode 120 may be arranged to reflect light upward.

The third substrate electrode 130 may include a material having conductivity. The third substrate electrode 130 may be electrically connected to the first light emitter 300 and the second light emitter 400. The third substrate electrode 130 may be disposed to be spaced apart from the one side of the first substrate electrode 110 and the one side of the second substrate electrode 120 in another direction perpendicular to the one direction. A length x of the third substrate electrode 130 in the one direction may be longer than a sum of a first length a1 of the first light emitter 300 and a second length a2 of the second light emitter 400, to be described later. In other words, when viewed from above, the first light emitter 300 and the second light emitter 400 may be positioned between one side of the third substrate electrode 130 and the other side opposite to the one side of the third substrate electrode 130. Furthermore, the third substrate electrode 130 may be arranged to reflect light upward.

The insulator 140 may be disposed among the first substrate electrode 110, the second substrate electrode 120, and the third substrate electrode 130. The first substrate electrode 110, the second substrate electrode 120, and the third substrate electrode 130 may be insulated by being spaced apart from each other by the insulator 140. The insulator 140 may be integrally formed with the partition wall 200. In other words, the insulator 140 may be connected to the partition wall 200 to insulate among the first substrate electrode 110, the second substrate electrode 120, and the third substrate electrode 130.

The partition wall 200 may be disposed on the substrate 100 and provide an accommodation space accommodating the first light emitter 300 and the second light emitter 400. The partition wall 200 may extend upward from the substrate 100. Furthermore, the partition wall 200 may include a side wall 210 inclined with respect to the substrate 100.

The first light emitter 300 may be disposed on the substrate 100 to be positioned in the accommodation space, and may generate light. A length of the first light emitter 300 in the one direction may be smaller than a length of the first light emitter 300 in the other direction perpendicular to the one direction. Hereinafter, the length of the first light emitter 300 in the one direction is referred to as a first length a1. Furthermore, the length of the first light emitter 300 in the other direction is referred to as a first width b1. Furthermore, one side of the first light emitter 300 may be disposed to face the second light emitter 400, and the other side opposite to the one side of the first light emitter 300 may be disposed to face the side wall 210. The one side and the other side of the first light emitter 300 may be surfaces extending along the other direction.

The first light emitter 300 may generate light having a first peak wavelength. The first light emitter 300 may generate light having a peak wavelength different from a peak wavelength of the second light emitter 400. For example, the first light emitter 300 may generate blue light. A spectrum of the light of the first light emitter 300 may have an FWHM (Full Width at Half Maximum) of 20 nm or less.

The second light emitter 400 may be disposed on the substrate 100 to be positioned in the accommodation space, and may generate light. The second light emitter 400 may generate light having a second peak wavelength. The second light emitter 400 may generate blue light. The second light emitter 400 and the first light emitter 300 may be formed in a similar or identical size. A length of the second light emitter 400 in the one direction may be smaller than a second width b2 being a length of the second light emitter 400 in the other direction. Hereinafter, the length of the second light emitter 400 in the one direction is referred to as a second length a2.

The second light emitter 400 may be disposed to be spaced apart from the first light emitter 300 in the one direction. One side of the second light emitter 400 may be disposed to face the one side of the first light emitter 300, and the other side opposite to the one side of the second light emitter 400 may be disposed to face the side wall 210. The one side and the other side of the second light emitter 400 may be surfaces extending along the other direction. The second light emitter 400 and the first light emitter 300 may be disposed such that a space between the second light emitter 400 and the first light emitter 300 overlaps a space between the one side of the first substrate electrode 110 and the one side of the second substrate electrode 120 in an up-down direction. Hereinafter, the space between the second light emitter 400 and the first light emitter 300 is referred to as an element separation space. Furthermore, a separation distance between the first light emitter 300 and the second light emitter 400 may be larger than the electrode separation distance 1. In other words, the one side of the first substrate electrode 110 and the one side of the second substrate electrode 120 may be disposed between the first light emitter 300 and the second light emitter 400. Accordingly, a portion of the first substrate electrode 110 and a portion of the second substrate electrode 120 may be exposed between the first light emitter 300 and the second light emitter 400. Furthermore, when viewed from above, a portion of the first light emitter 300 disposed on the first substrate electrode 110 may be surrounded by the first substrate electrode 110. When viewed from above, a portion of the second light emitter 400 disposed on the second substrate electrode 120 may be surrounded by the second substrate electrode 120. Accordingly, reflection of light emitted from a side surface of the light emitter is increased, so that light extraction efficiency may be improved. Hereinafter, the separation distance between the first light emitter 300 and the second light emitter 400 is referred to as an element separation distance c.

Furthermore, a sum of the second length a2 of the second light emitter 400, the first length a1 of the first light emitter 300, and the element separation distance c may be larger than the first width b1 of the first light emitter 300. Furthermore, the second length a2 of the second light emitter 400 or the first length a1 of the first light emitter 300 may be larger than the element separation distance c.

Furthermore, a ratio between the element separation distance c and a thickness d of any one of the first light emitter 300 and the second light emitter 400 may be expressed by Equation 1 below.

$$0.4 < \frac{c}{d} < 4 \qquad [ Equation 1 ]$$

In other words, the ratio between the element separation distance c and the thickness d of any one of the first light emitter 300 and the second light emitter 400 may be greater than 0.4 and less than 4. That is, a ratio of a separation distance between the first light emitter 300 and the second light emitter 400 to a thickness of the first light emitter 300 may be greater than 0.4 and less than 4. By this ratio, since the molding layer 700 may easily penetrate between the first light emitter 300 and the second light emitter 400, a void may be prevented from occurring between the first light emitter 300 and the second light emitter 400. Furthermore, since light emitted from the one side of the first light emitter 300 and the one side of the second light emitter 400 facing each other may be mixed in the element separation space, a luminous intensity may be prevented from decreasing in an area where the light emitter is not disposed.

As another example, the second light emitter 400 may generate light of a long wavelength. The first light emitter 300 may generate light of a short wavelength. The second light emitter 400 may generate light of a second peak wavelength different from the first peak wavelength. For example, the second light emitter 400 may generate green light. A difference between the first peak wavelength and the second peak wavelength may be 59 nm to 150 nm. A spectrum of the light of the second light emitter 400 may have an FWHM of 50 nm or less. In other words, the FWHM of the light of the second light emitter 400 may be larger than the FWHM of the light of the first light emitter 300.

The first light emitter 300 and the second light emitter 400 may be disposed to be spaced apart from the side wall 210. A separation distance from a center between an end of the first light emitter 300 in the other direction and an end of the second light emitter 400 in the other direction to a lower end of the side wall 210 may be defined as a first side wall separation distance T1. The first side wall separation distance T1 may be a distance in a horizontal direction from a bottom of the accommodation space. A first space may be formed in the accommodation space of the partition wall 200 by the first side wall separation distance T1. A separation distance in the one direction from a center of the other side of the second light emitter 400 to the lower end of the side wall 210 may be defined as a second side wall separation distance T2. The second side wall separation distance T2 may be a distance in the horizontal direction from the bottom of the accommodation space. A second space may be formed in the accommodation space of the partition wall 200 by the second side wall separation distance T2. The first side wall separation distance T1 may be larger than the second side wall separation distance T2. In other words, the first space may be larger than the second space. A surface having a relatively long length among side surfaces of the light emitter is disposed toward the second space, and a surface having a relatively short length among the side surfaces of the light emitter is disposed toward the first space, thereby improving a light quantity imbalance caused by a difference in the side surface lengths of the light emitter.

Meanwhile, each of the first light emitter 300 and the second light emitter 400 may include a first conductivity type semiconductor layer, an active layer, a second conductivity type semiconductor layer, and a light transmitting layer.

The first conductivity type semiconductor layer may be formed of a nitride-based semiconductor material doped with an impurity of a first conductivity type. For example, the first conductivity type semiconductor layer may be an n-type semiconductor layer increasing electron mobility by being doped with an n-type impurity such as Si. However, the first conductivity type semiconductor layer is not limited thereto, and may be a p-type semiconductor layer doped with a p-type impurity such as Mg.

Hereinafter, the first conductivity type semiconductor layer included in the first light emitter 300 is referred to as a first A-type conductivity-type semiconductor layer 310. The first conductivity type semiconductor layer included in the second light emitter 400 is referred to as a second A-type conductivity-type semiconductor layer 410. Furthermore, an A-type and a B-type may mean an n-type or a p-type. In other words, the A-type may be any one of the n-type and the p-type. The B-type may be the other one of the n-type and the p-type.

The active layer may be formed in a single quantum well structure or a multiple quantum well (MQW) structure. The active layer may be stacked on the first conductivity type semiconductor layer. The active layer may generate light from a combination of electrons and holes respectively injected into the first conductivity type semiconductor layer and the second conductivity type semiconductor layer. The active layer may include a well layer formed of a nitride-based semiconductor material including indium (In) and a barrier layer formed of a nitride-based semiconductor material. Unlike the well layer, the barrier layer may not include indium, but is not limited thereto and may include a small amount of indium. For example, the well layer may be formed of a semiconductor material having a compositional formula of In_{z}Ga_{1-z}N(0≤z≤1). In addition, the barrier layer may be formed of a semiconductor material having a compositional formula of AlₓIn_{y}Ga_{1-x-y}N(0≤x≤1, 0≤y≤1).

Hereinafter, the active layer included in the first light emitter 300 is referred to as a first active layer 320. The active layer included in the second light emitter 400 is referred to as a second active layer 420.

The second conductivity type semiconductor layer may be stacked on the active layer. The second conductivity type semiconductor layer may be formed of a nitride-based semiconductor material doped with an impurity of a second conductivity type different from the first conductivity type. For example, the second conductivity type semiconductor layer may be a p-type semiconductor layer increasing hole mobility by being doped with a p-type impurity such as Mg. However, the present disclosure is not limited thereto, and the second conductivity type semiconductor layer may be an n-type semiconductor layer doped with an n-type impurity such as Si. The second conductivity type semiconductor layer included in the first light emitter 300 is referred to as a first B-type conductivity-type semiconductor layer 330. The second conductivity type semiconductor layer included in the second light emitter 400 is referred to as a second B-type conductivity-type semiconductor layer 430.

The light transmitting layer may be stacked on the second conductivity type semiconductor layer. The light transmitting layer may be an insulating or conductive substrate, and may be an insulating or conductive substrate bonded by bonding. Furthermore, the light transmitting layer may be a substrate for growing the first conductivity type semiconductor layer, the active layer, and the second conductivity type semiconductor layer. For example, the light transmitting layer may include at least one of a silicon carbide substrate, a silicon substrate, a gallium nitride substrate, an aluminum nitride substrate, a sapphire substrate, and an Insulation Patterned Sapphire Substrate (IPSS).

Hereinafter, the light transmitting layer included in the first light emitter 300 is referred to as a first light transmitting layer 340. The light transmitting layer included in the second light emitter 400 is referred to as a second light transmitting layer 440.

The first A-type conductivity-type semiconductor layer 310 of the first light emitter 300 may be electrically connected to the first substrate electrode 110. The first B-type conductivity-type semiconductor layer 330 of the first light emitter 300 may be electrically connected to the third substrate electrode 130. The second A-type conductivity-type semiconductor layer 410 of the second light emitter 400 may be electrically connected to the third substrate electrode 130. The second B-type conductivity-type semiconductor layer 430 of the second light emitter 400 may be electrically connected to the second substrate electrode 120. The first light emitter 300 and the second light emitter 400 may be connected in series. In other words, a current or a voltage may flow in an order of the first substrate electrode 110, the first light emitter 300, the third substrate electrode 130, the second light emitter 400, and the second substrate electrode 120, or may flow in an order of the second substrate electrode 120, the second light emitter 400, the third substrate electrode 130, the first light emitter 300, and the first substrate electrode 110.

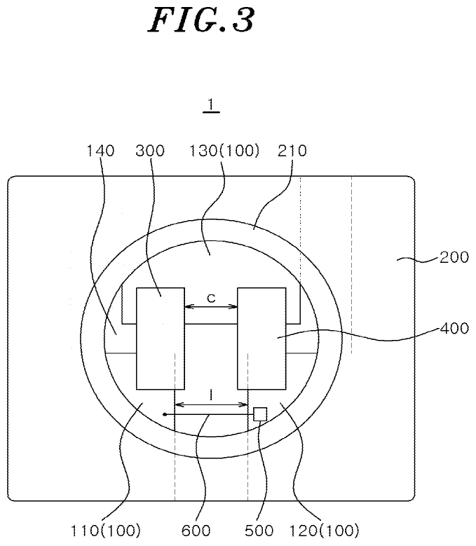

Meanwhile, referring further to FIG. 3, although the electrode separation distance 1 is described as being smaller than the element separation distance c in the above description, the present disclosure is not limited thereto, and the electrode separation distance 1 may be formed to be larger than the element separation distance c. In other words, when viewed from above, at least a portion of the one side of the first substrate electrode 110 may be covered by the first light emitter 300. Furthermore, at least a portion of the one side of the second substrate electrode 120 may be covered by the second light emitter 400.

The auxiliary element 500 may be disposed on at least one of the first substrate electrode 110, the second substrate electrode 120, and the third substrate electrode 130. The auxiliary element 500 may be disposed to be closer to any one of the first light emitter 300 and the second light emitter 400. Furthermore, the auxiliary element 500 may be disposed to be close to a light emitter generating light of a relatively longer peak wavelength among the first light emitter 300 and the second light emitter 400. In other words, the auxiliary element 500 may be disposed on the second substrate electrode 120. The number of auxiliary elements 500 may be less than the number of light emitters disposed on the substrate 100. The auxiliary element 500 may adjust or diffuse a traveling path of light generated from the first light emitter 300 and the second light emitter 400 to promote mixing of light and suppress a color separation phenomenon.

The conductor 600 may include a conductive material to electrically connect the auxiliary element 500 to any one of the first substrate electrode 110, the second substrate electrode 120, and the third substrate electrode 130. In other words, the conductor 600 may extend in one direction and be connected to the first substrate electrode 110 and the auxiliary element 500 to electrically connect the first substrate electrode 110 and the auxiliary element 500. For example, the conductor 600 may be a wire.

The molding layer 700 may be disposed in the accommodation space of the partition wall 200 to cover the first light emitter 300 and the second light emitter 400. The molding layer 700 may be formed to allow light of the first light emitter 300 and the second light emitter 400 to pass through. Furthermore, one or more particles 710 may be provided in the molding layer 700. The one or more particles 710 may include a material capable of converting a wavelength of light of the first light emitter 300 and the second light emitter 400. In other words, the particle 710 may include at least one of materials such as a phosphor being a wavelength conversion material, KSF, CASN, or SiAlON. For example, the particle 710 may generate red light so that the light emitting device 1 emits white light. Furthermore, the molding layer 700 may be provided as the insulator 140.

The number of peaks in a spectrum of light passing through the molding layer 700 may be greater than the number of peaks in a spectrum of light generated from the first light emitter 300 and the second light emitter 400 in a state where the molding layer 700 is removed.

Hereinafter, an operation and an effect of the light emitting device 1 according to the first embodiment of the present disclosure will be described.

Since the separation distance between the first light emitter 300 and the second light emitter 400 of the light emitting device 1 of an embodiment may be formed close to each other, the beam angle of the light emitting device 1 is formed to be close to a circular shape, and color separation may be prevented from occurring.

Furthermore, the first light emitter 300 and the second light emitter 400 may be connected in series.

Furthermore, when viewed from above, since the one side of the first substrate electrode 110 and the one side of the second substrate electrode 120 may be disposed between the first light emitter 300 and the second light emitter 400, light generated from the one side of the first light emitter 300 and the one side of the second light emitter 400 may be mixed while being reflected by the first substrate electrode 110 and the second substrate electrode 120.

Furthermore, since the first side wall separation distance T1 may be formed to be larger than the second side wall separation distance T2, the first space formed by the first side wall separation distance T1 may be formed to be larger than the second space formed by the second side wall separation distance T2. In other words, since light generated between the first light emitter 300 and the second light emitter 400 travels in the other direction and may be efficiently mixed in the first space wider than the second space, a color separation phenomenon may be suppressed.

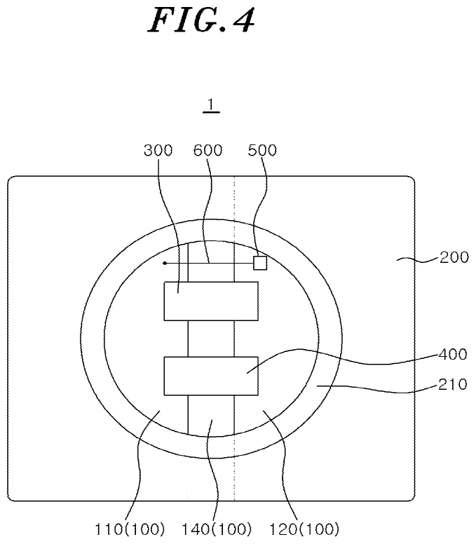

Hereinafter, referring further to FIG. 4, a light emitting device 1 according to a second embodiment of the present disclosure will be described. In describing the second embodiment, since there is a difference in that the first substrate electrode 110 and the second substrate electrode 120 are disposed to be spaced apart in the other direction, the description will focus on this difference.

The first substrate electrode 110 and the second substrate electrode 120 may be disposed to be spaced apart in a direction perpendicular to a direction in which the first light emitter 300 and the second light emitter 400 are spaced apart. In other words, the one side of the first substrate electrode 110 may be disposed to be perpendicular to the one side of the first light emitter 300 and the one side of the second light emitter 400. Furthermore, the one side of the second substrate electrode 120 may be disposed to be perpendicular to the one side of the first light emitter 300 and the one side of the second light emitter 400.

The first substrate electrode 110 may be connected to the first light emitter 300 and the second light emitter 400. In other words, the first substrate electrode 110 may be connected to the first A-type conductivity-type semiconductor layer 310 of the first light emitter 300 and the second A-type conductivity-type semiconductor layer 410 of the second light emitter 400. A length of the first substrate electrode 110 in the one direction may be longer than a sum of the length of the first light emitter 300 in the one direction and the length of the second light emitter 400 in the one direction.

The second substrate electrode 120 may be connected to the first light emitter 300 and the second light emitter 400. In other words, the second substrate electrode 120 may be connected to the second B-type conductivity-type semiconductor layer 430 of the second light emitter 400 and the first B-type conductivity-type semiconductor layer 330 of the first light emitter 300. A length of the second substrate electrode 120 in the one direction may be longer than a sum of the length of the first light emitter 300 in the one direction and the length of the second light emitter 400 in the one direction.

The auxiliary element 500 may be disposed on at least one of the first substrate electrode 110 and the second substrate electrode 120. The auxiliary element 500 may be disposed to be closer to any one of the first light emitter 300 and the second light emitter 400. The auxiliary element 500 may be disposed to be closer to a light emitter having a lower driving voltage among the first light emitter 300 and the second light emitter 400. The auxiliary element 500 may be disposed on the second substrate electrode 120 to be disposed closer to the first light emitter 300 than the second light emitter 400, but the present disclosure is not limited thereto.

The conductor 600 may be connected to the auxiliary element 500 and any one of the first substrate electrode 110 and the second substrate electrode 120. In other words, the conductor 600 may extend in the other direction and be connected to the auxiliary element 500 and the first substrate electrode 110.

Hereinafter, an operation and an effect of the light emitting device 1 according to the second embodiment of the present disclosure will be described.

The first light emitter 300 and the second light emitter 400 of the light emitting device 1 may be connected in parallel to each other.

Furthermore, since light may be reflected and mixed in an area positioned between the first light emitter 300 and the second light emitter 400 in the first substrate electrode 110, a color separation phenomenon may be suppressed.

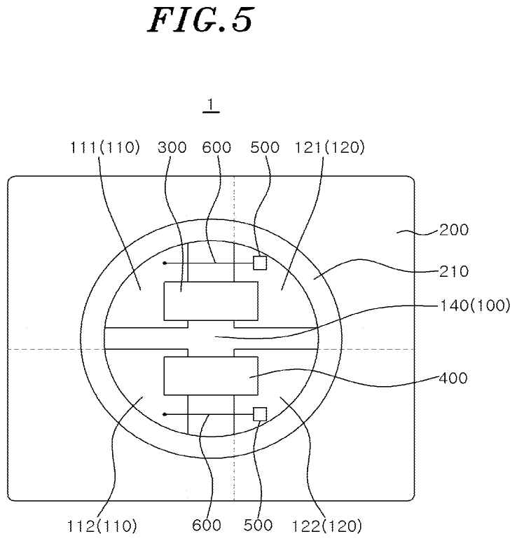

Hereinafter, referring further to FIG. 5, a light emitting device 1 according to a third embodiment of the present disclosure will be described. In describing the third embodiment, since there is a difference in that the first substrate electrode 110 includes a first sub-electrode 111 and a second sub-electrode 112, and the second substrate electrode 120 includes a third sub-electrode 121 and a fourth sub-electrode 122, the description will focus on this difference. Meanwhile, although each of the plurality of substrate electrodes is illustrated as being formed as one substrate electrode in the drawings according to the present embodiment, the present disclosure is not necessarily limited thereto, and each substrate electrode may include a plurality of sub-electrodes.

The first sub-electrode 111 and the second sub-electrode 112 may be disposed to be spaced apart from each other in the one direction. The first sub-electrode 111 may be connected to the first light emitter 300. In other words, the first sub-electrode 111 may be connected to the first A-type conductivity-type semiconductor layer 310 of the first light emitter 300.

The second sub-electrode 112 may be connected to the second light emitter 400. In other words, the second sub-electrode 112 may be connected to the second A-type conductivity-type semiconductor layer 410 of the second light emitter 400. A separation distance between the second sub-electrode 112 and the first sub-electrode 111 may be shorter than the separation distance between the first light emitter 300 and the second light emitter 400. Furthermore, when viewed from above, a space between the second sub-electrode 112 and the first sub-electrode 111 may be disposed to overlap a space between the first light emitter 300 and the second light emitter 400.

The third sub-electrode 121 and the fourth sub-electrode 122 may be disposed to be spaced apart from each other in the one direction. The third sub-electrode 121 may be spaced apart from the first sub-electrode 111 in the other direction. Furthermore, the third substrate electrode 130 may be connected to the first light emitter 300. In other words, the third substrate electrode 130 may be connected to the first B-type conductivity-type semiconductor layer 330 of the first light emitter 300.

The fourth sub-electrode 122 may be spaced apart from the second sub-electrode 112 in the other direction. Furthermore, the fourth sub-electrode 122 may be connected to the second light emitter 400. In other words, the fourth sub-electrode 122 may be connected to the second B-type conductivity-type semiconductor layer 430 of the second light emitter 400. A separation distance between the fourth sub-electrode 122 and the third sub-electrode 121 may be shorter than the separation distance between the first light emitter 300 and the second light emitter 400. Furthermore, when viewed from above, a space between the third sub-electrode 121 and the fourth sub-electrode 122 may be disposed to overlap the space between the first light emitter 300 and the second light emitter 400.

A plurality of auxiliary elements 500 may be formed. Any one of the plurality of auxiliary elements 500 may be disposed on the third sub-electrode 121. Furthermore, another one of the plurality of auxiliary elements 500 may be disposed on the fourth sub-electrode 122. The first light emitter 300 and the second light emitter 400 may be disposed between the plurality of auxiliary elements 500. The number of the plurality of auxiliary elements 500 may be identical to the number of light emitters.

A plurality of conductors 600 may be formed. Any one of the plurality of conductors 600 may be connected to the first sub-electrode 111 and any one of the plurality of auxiliary elements 500. Furthermore, another one of the plurality of conductors 600 may be connected to the second sub-electrode 112 and another one of the plurality of auxiliary elements 500.

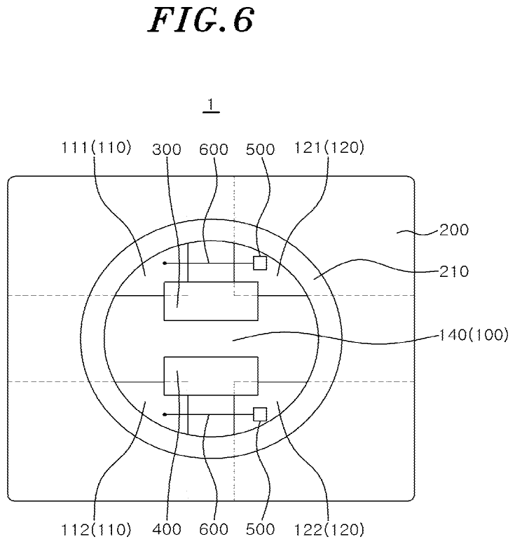

Meanwhile, although the separation distance between the second sub-electrode 112 and the first sub-electrode 111 is described as being shorter than the separation distance between the first light emitter 300 and the second light emitter 400 in the above description, the present disclosure is not limited thereto. In other words, referring further to FIG. 6, the separation distance between the second sub-electrode 112 and the first sub-electrode 111 may be longer than the separation distance between the first light emitter 300 and the second light emitter 400. Furthermore, although the separation distance between the fourth sub-electrode 122 and the third sub-electrode 121 is described as being shorter than the separation distance between the first light emitter 300 and the second light emitter 400 in the above description, the present disclosure is not limited thereto. In other words, the separation distance between the fourth sub-electrode 122 and the third sub-electrode 121 may be longer than the separation distance between the first light emitter 300 and the second light emitter 400.

Hereinafter, an operation and an effect of the light emitting device 1 according to the third embodiment of the present disclosure will be described.

The first light emitter 300 and the second light emitter 400 may be independently driven and controlled by the first sub-electrode 111, the second sub-electrode 112, the third sub-electrode 121, and the fourth sub-electrode 122 of the embodiment of the present disclosure.

Furthermore, when viewed from above, since light may be reflected and mixed by the first sub-electrode 111, the second sub-electrode 112, the third sub-electrode 121, and the fourth sub-electrode 122 in an area between the first light emitter 300 and the second light emitter 400, a color separation phenomenon may be suppressed.

The light emitting device 1 according to the embodiment of the present disclosure may be applied to various light emitting systems.

Hereinafter, a light emitting system including the light emitting device 1 according to the embodiment of the present disclosure will be described.

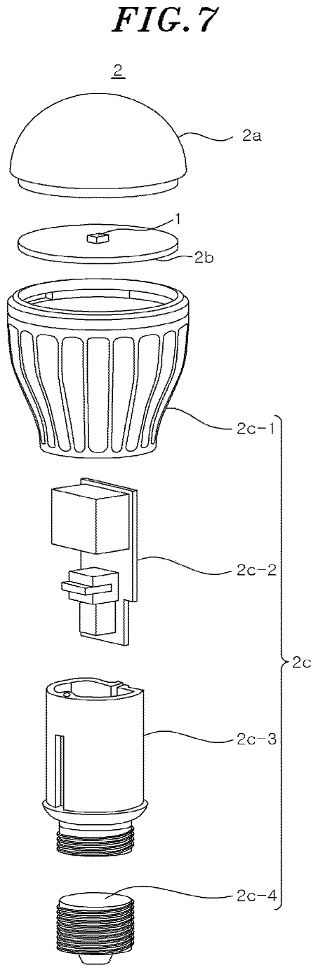

FIG. 7 is a view illustrating a light emitting system according to the first embodiment of the present disclosure. Referring to FIG. 7, the light emitting system according to the first embodiment may be a lighting device 2 including one or more light emitting devices 1.

The lighting device 2 may include a diffusion cover 2a, a substrate 2b, and a body portion 2c. The body portion 2c may accommodate the substrate 2b and the light emitting device 1. The diffusion cover 2a may be disposed on an upper side of the body portion 2c to cover an upper portion of the light emitting device 1.

The body portion 2c may accommodate and support the substrate 2b. The body portion 2c is not limited as long as it has a form supplying electric power to the substrate 2b and the light emitting device 1. The body portion 2c may include a body case 2c-1, a power supply device 2c-2, a power case 2c-3, and a power connection portion 2c-4.

The power supply device 2c-2 may be accommodated in the power case 2c-3 to be electrically connected to the light emitting device 1, and may include at least one IC chip. The IC chip may adjust, convert, or control a characteristic of power supplied to the light emitting device 1.

The power case 2c-3 may accommodate and support the power supply device 2c-2. The power case 2c-3 may be positioned inside the body case 2c-1.

The power connection portion 2c-4 may be disposed at a lower end of the power case 2c-3 and coupled to the power case 2c-3. The power connection portion 2c-4 may be electrically connected to the power supply device 2c-2 disposed inside the power case 2c-3, thereby serving as a passage through which external power may be supplied to the power supply device 2c-2.

The substrate 2b is not limited as long as it is a substrate supporting the light emitting device 1, and for example, may be a PCB including a wiring. The substrate 2b may have a shape corresponding to a fixing portion of an upper portion of the body case 2c-1 to be stably fixed to the body case 2c-1. The substrate 2b may be disposed on the body case 2c-1 and electrically connected to the power supply device 2c-2.

The diffusion cover 2a may be disposed on the substrate 2b and fixed to the body case 2c-1 to cover the substrate 2b and the light emitting device 1. The diffusion cover 2a may have a light-transmitting material. When a shape and a light transmittance of the diffusion cover 2a are adjusted, a directivity characteristic of the lighting device 2 may be adjusted. Accordingly, the diffusion cover 2a may be modified into various shapes according to a purpose of use and an application aspect of the lighting device 2.

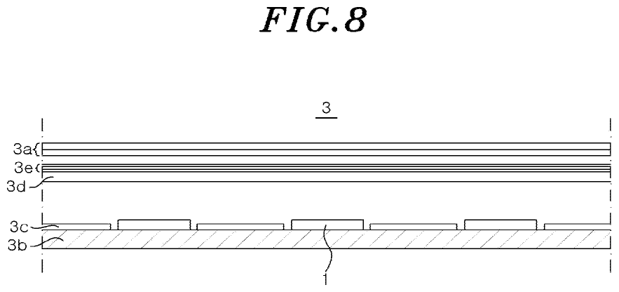

FIG. 8 is a cross-sectional view of a light emitting system according to the second embodiment of the present disclosure. The light emitting system of the second embodiment may be a display device 3 including at least one light emitting device 1.

The display device 3 may include a display panel 3a, a backlight unit providing light to the display panel 3a, and a panel guide supporting a lower edge of the display panel 3a.

The display panel 3a may be a liquid crystal display panel including a liquid crystal layer, but is not limited thereto. A gate driving PCB supplying a driving signal to a gate line may be disposed at an edge of the display panel 3a. The gate driving PCB is not configured as a separate PCB, and may be formed on a thin-film transistor substrate. A pixel of the display panel 3a may be an LED display implemented by the light emitting device 1 of the present disclosure. When the display panel 3a is an LED display, the backlight unit described later may be omitted.

The backlight unit may include at least one substrate and a plurality of light emitting devices 1. Furthermore, the backlight unit may further include a bottom cover 3b, a reflection sheet 3c, a diffusion plate 3d, and a plurality of optical sheets 3e.

The bottom cover 3b may be opened upward to accommodate the substrate, the light emitting device 1, the reflection sheet 3c, the diffusion plate 3d, and the plurality of optical sheets 3e. Furthermore, the bottom cover 3b may be coupled to the panel guide. The substrate may be positioned under the reflection sheet 3c to be disposed in a form surrounded by the reflection sheet 3c. However, the present disclosure is not limited thereto, and when a reflective material is coated on a surface, the substrate may be positioned on the reflection sheet 3c. Furthermore, the substrate may be formed in plurality and disposed in a form in which the plurality of substrates are arranged side by side, but is not limited thereto, and may be formed as a single substrate.

The plurality of light emitting devices 1 may be regularly arranged in a constant pattern on the substrate. Furthermore, a lens may be disposed on each of the light emitting devices 1 to improve uniformity of light emitted from the light emitting device 1.

The diffusion plate 3d and the plurality of optical sheets 3e may be positioned above the light emitting device 1. Light emitted from the light emitting device 1 may pass through the diffusion plate 3d and the plurality of optical sheets 3e to be supplied to the display panel 3a in a form of a surface light source.

As such, the light emitting device 1 according to the embodiments of the present disclosure may be applied to a direct-type display device 3.

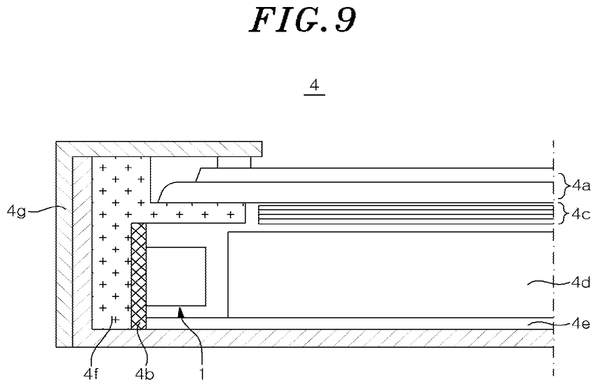

FIG. 9 is a cross-sectional view of a light emitting system according to a third embodiment of the present disclosure. The light emitting system according to the third embodiment may be a display device 4 including at least one light emitting device 1.

The display device 4 provided with a backlight unit may include a display panel 4a displaying an image, and the backlight unit disposed on a rear surface of the display panel 4a and irradiating light. Furthermore, the display device 4 may include a frame supporting the display panel 4a and accommodating the backlight unit, and a cover 4g surrounding the display panel 4a.

The display panel 4a is not particularly limited, and for example, may be a liquid crystal display panel including a liquid crystal layer. Agate driving PCB supplying a driving signal to a gate line may be further disposed at an edge of the display panel 4a. The gate driving PCB is not configured as a separate PCB, and may be formed on a thin-film transistor substrate. The display panel 4a is fixed by covers 4g positioned on upper and lower portions thereof, and the cover 4g positioned on the lower portion may be coupled to the backlight unit.

The backlight unit providing light to the display panel 4a includes a lower cover 4f having a portion of an upper surface opened, a substrate 4b disposed at one inner side of the lower cover 4f, the light emitting device 1, and a light guide plate 4d positioned parallel to the light emitting device 1 to convert point light into surface light. Furthermore, the backlight unit may further include a plurality of optical sheets 4c positioned on the light guide plate 4d to diffuse and condense light, and a reflection sheet 4e disposed under the light guide plate 4d to reflect light traveling downward of the light guide plate 4d toward the display panel 4a.

The substrate 4b may support the light emitting device 1. The substrate 4b is not limited as long as it is electrically connected to the light emitting device 1, and may be a PCB. The substrate 4b may support the light emitting device 1 such that the light emitting device 1 is spaced apart from the light guide plate 4d.

Light emitted from the light emitting device 1 may be incident on the light guide plate 4d and supplied to the display panel 4a through the plurality of optical sheets 4c. Through the light guide plate 4d and the plurality of optical sheets 4c, a point light source emitted from the light emitting device 1 may be transformed into a surface light source. As such, the light emitting device 1 according to the embodiments of the present disclosure may be applied to an edge-type display device 4 as in the present embodiment.

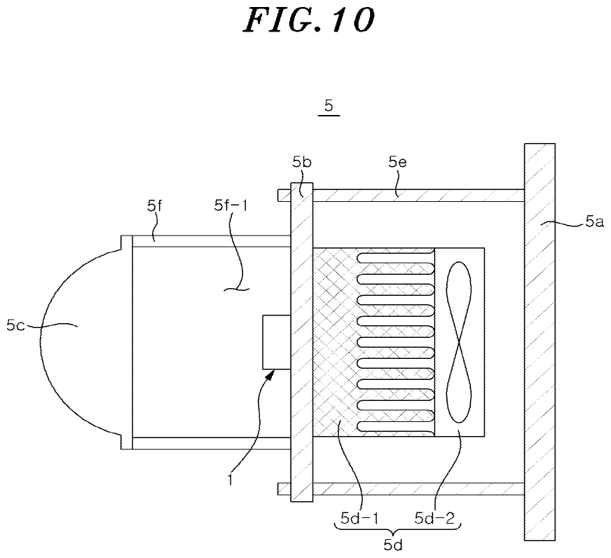

FIG. 10 is a cross-sectional view of a light emitting system according to a fourth embodiment of the present disclosure. The light emitting system of the fourth embodiment may be a head lamp 5 including at least one light emitting device 1.

Referring to FIG. 10, the head lamp 5 may include a lamp body 5a, a substrate 5b, a light emitting device 1, and a cover lens 5c. Furthermore, the head lamp 5 may further include a heat dissipation unit 5d, a support rack 5e, and a connection member 5f.

The substrate 5b may be fixed by the support rack 5e and disposed to be spaced apart from the lamp body 5a. The substrate 5b is not limited as long as it is a substrate supporting the light emitting device 1, and may be a substrate having a conductive pattern such as a PCB.

The light emitting device 1 is disposed on the substrate 5b, and may be supported and fixed by the substrate 5b. Furthermore, the light emitting device 1 may be electrically connected to external power through the conductive pattern of the substrate 5b.

The cover lens 5c may be positioned on an optical path along which light emitted from the light emitting device 1 travels. For example, the cover lens 5c may be disposed to be spaced apart from the light emitting device 1 by the connection member 5f, and may be disposed at a position corresponding to an emission direction of light emitted from the light emitting device 1. At least one of a beam angle and a color of light emitted to the outside from the head lamp 5 may be adjusted by the cover lens 5c.

The connection member 5f may fix the cover lens 5c to the substrate 5b. Furthermore, the connection member 5f may be disposed to surround the light emitting device 1, thereby serving as a light guide providing a light emission path 5f-1 of light. The connection member 5f may be formed of a light reflective material or coated with a light reflective material.

The heat dissipation unit 5d may include at least one of a heat dissipation fin 5d-1 and a heat dissipation fan 5d-2. The heat dissipation unit 5d may emit heat generated in the light emitting device 1 to the outside.

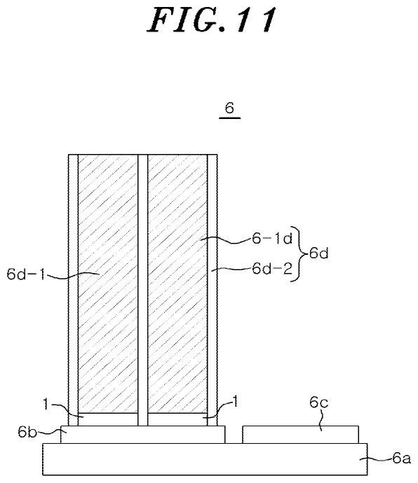

FIG. 11 is a cross-sectional view of a light emitting system according to a fifth embodiment of the present disclosure. The light emitting system of the fifth embodiment may be an optical communication interconnector 6 including at least one light emitting device 1.

The optical communication interconnector 6 may include a substrate 6a, a frame 6b, a D2D interface 6c, and a light transmission unit 6d.

The substrate 6a may be a package substrate supporting at least one of the substrate 6a, the frame 6b, the D2D interface 6c, and the light transmission unit 6d, or a main logic chip (e.g., CPU) itself performing actual operations.

One or more light emitting devices 1 may be disposed on the substrate 6a. The light emitting device 1 may perform a role of an ‘optical transmission unit’ in the optical communication interconnector 6. The light emitting device 1 may include an array of the first light emitter 300 and the second light emitter 400 and an integral or individual light transmitting layer (lens array) for condensing light emitted from each of the first light emitter 300 and the second light emitter 400 therein as described in the previous embodiments.

The light emitting device 1 may be supported by the frame 6b located under the light emitting device 1. The frame 6b may mechanically and stably fix the light emitting device 1, and ensure precise height alignment with the light transmission unit 6d to be described later.

The D2D interface 6c may be disposed side by side with the light emitting device 1 on the substrate 6a. The D2D interface 6C may be an electrical passage for transmitting and receiving an optical signal, connecting between the main logic chip corresponding to the substrate 6a and the light emitting device 1. That is, a high-speed electrical data signal generated in the main logic chip may be transmitted to the light emitting device 1 through the D2D interface 6c.

The light transmission unit 6d may include a fiber bundle (Fiber Bundle) formed by bundling numerous individual optical fibers 6d-1, and a housing (Ferrule) 6d-2 fixing the fiber bundle in a lattice structure. Through the housing 6d-2, a core of each optical fiber 6d-1 may be aligned to exactly correspond to each micro light emitter in the light emitting device 1 on a one-to-one basis.

The light emitting device 1 according to the embodiment of the present disclosure may be applied to various lighting, displays, BLUs, vehicle lighting devices, and the like in addition to the above-described light emitting system.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

[Explanation of reference signs]

| | |
|---|---|
| 1: light emitting device | 100: substrate |
| 110: first substrate electrode | 111: first sub-electrode |
| 112: second sub-electrode | 120: second substrate electrode |
| 121: third sub-electrode | 122: fourth sub-electrode |
| 130: third substrate electrode | 140: insulator |
| 200: partition wall | 210: side wall |
| 300: first light emitter | 310: first A-type conductive |
| | semiconductor layer |
| 320: first active layer | 330: first B-type conductive |
| | semiconductor layer |
| 340: first light transmitting layer | |
| 400: second light emitter | 410: second A-type conductive |
| | semiconductor layer |
| 420: second active layer | 430: second B-type conductive |
| | semiconductor layer |
| 440: second light transmitting layer | |
| 500: auxiliary element | 600: conductor |
| 700: molding layer | 710: particles |

1. A light emitting device comprising:
a substrate;
a first light emitter disposed on the substrate and configured to generate light; and
a second light emitter disposed on the substrate, spaced apart from the first light emitter in a first direction, and configured to generate light,
wherein the substrate includes:
a first substrate electrode electrically connected to the first light emitter; and
a second substrate electrode electrically connected to the second light emitter and spaced apart from the first substrate electrode,
wherein one side of the first substrate electrode is disposed to face one side of the second substrate electrode, and
wherein at least one of the one side of the first substrate electrode and the one side of the second substrate electrode is disposed between the first light emitter and the second light emitter.

2. The light emitting device of claim 1, wherein a separation distance between the first substrate electrode and the second substrate electrode in the first direction is smaller than a separation distance between the first light emitter and the second light emitter in the first direction.

3. The light emitting device of claim 1, wherein the first light emitter comprises:
a first A-type conductivity-type semiconductor layer;
a first active layer stacked on the first A-type conductivity-type semiconductor layer;
a first B-type conductivity-type semiconductor layer stacked on the first active layer; and
a first light transmitting layer stacked on the first B-type conductivity-type semiconductor layer,
wherein the first A-type conductivity-type semiconductor layer is connected to the first substrate electrode,
wherein the second light emitter comprises:
a second A-type conductivity-type semiconductor layer;
a second active layer stacked on the second A-type conductivity-type semiconductor layer;
a second B-type conductivity-type semiconductor layer stacked on the second active layer; and
a second light transmitting layer stacked on the second B-type conductivity-type semiconductor layer, and
wherein the second B-type conductivity-type semiconductor layer is connected to the second substrate electrode.

4. The light emitting device of claim 3, wherein the substrate further comprises:
a third substrate electrode electrically connected to the first light emitter and the second light emitter and spaced apart from the first substrate electrode and the second substrate electrode, wherein the first B-type conductivity-type semiconductor layer is connected to the third substrate electrode, and
wherein the second A-type conductivity-type semiconductor layer of the second light emitter is connected to the third substrate electrode.

5. The light emitting device of claim 1, wherein the first light emitter is configured to emit light of a first peak wavelength, the second light emitter is configured to emit light of a second peak wavelength, and a difference between the first peak wavelength and the second peak wavelength is 59 nm to 150 nm.

6. The light emitting device of claim 1, wherein the first light emitter and the second light emitter are formed such that a length thereof in a second direction perpendicular to the first direction is greater than a length thereof in the first direction.

7. The light emitting device of claim 6, wherein a sum of a length of the first light emitter in the first direction, a length of the second light emitter in the first direction, and a separation distance between the first light emitter and the second light emitter is larger than a length of the first light emitter in the second direction.

8. The light emitting device of claim 6, wherein a length of the first light emitter in the first direction is larger than a separation distance between the first light emitter and the second light emitter.

9. The light emitting device of claim 1, further comprising:
a partition wall disposed on the substrate to provide an accommodation space accommodating the first light emitter and the second light emitter and including a side wall inclined with respect to the substrate.

10. The light emitting device of claim 9, wherein one side of the first light emitter is disposed to face the second light emitter, and
wherein a separation distance from a center between an end of the first light emitter in a second direction perpendicular to the first direction and an end of the second light emitter in the second direction to a lower end of the side wall is larger than a separation distance from a center of the second side opposite to the one side of the first light emitter to the lower end of the side wall.

11. The light emitting device of claim 9, further comprising:
a molding layer disposed in the accommodation space of the partition wall to cover the first light emitter and the second light emitter.

12. The light emitting device of claim 11, wherein a phosphor including a wavelength conversion material is provided in the molding layer.

13. The light emitting device of claim 4, wherein the substrate further comprises:
an insulator disposed among the first substrate electrode, the second substrate electrode, and the third substrate electrode.

14. The light emitting device of claim 1, further comprising:
an auxiliary element disposed on the second substrate electrode.

15. A light emitting device comprising:
a substrate;
a first light emitter disposed on the substrate and configured to generate light; and
a second light emitter disposed on the substrate, spaced apart from the first light emitter in a first direction, and configured to generate light,
wherein the substrate includes:
a first substrate electrode electrically connected to the first light emitter; and
a second substrate electrode electrically connected to the second light emitter and spaced apart from the first substrate electrode, and
wherein a ratio of a separation distance between the first light emitter and the second light emitter to a thickness of the first light emitter is greater than 0.4 and less than 4.

16. A light emitting device comprising:
a substrate;
a first light emitter disposed on the substrate and configured to generate light; and
a second light emitter disposed on the substrate, to be spaced apart from the first light emitter in a first direction, and configured to generate light,
wherein the substrate includes:
a first substrate electrode electrically connected to the first light emitter and the second light emitter; and
a second substrate electrode spaced apart from the first substrate electrode in a second direction perpendicular to the first direction, and electrically connected to the first light emitter and the second light emitter.

17. The light emitting device of claim 16, wherein the first light emitter comprises:
a first A-type conductivity-type semiconductor layer;
a first active layer stacked on the first A-type conductivity-type semiconductor layer;
a first B-type conductivity-type semiconductor layer stacked on the first active layer; and
a first light transmitting layer stacked on the first B-type conductivity-type semiconductor layer,
wherein the second light emitter comprises:
a second A-type conductivity-type semiconductor layer;
a second active layer stacked on the second A-type conductivity-type semiconductor layer;
a second B-type conductivity-type semiconductor layer stacked on the second active layer; and
a second light transmitting layer stacked on the second B-type conductivity-type semiconductor layer, and
wherein the first A-type conductivity-type semiconductor layer is connected to the first substrate electrode,
the first B-type conductivity-type semiconductor layer is connected to the second substrate electrode,
the second A-type conductivity-type semiconductor layer is connected to the first substrate electrode, and
the second B-type conductivity-type semiconductor layer is connected to the second substrate electrode.

18. The light emitting device of claim 17, wherein the first substrate electrode comprises:
a first sub-electrode connected to the first A-type conductivity-type semiconductor layer; and
a second sub-electrode spaced apart from the first sub-electrode in the first direction, and connected to the second A-type conductivity-type semiconductor layer, and
the second substrate electrode comprises:
a third sub-electrode spaced apart from the first sub-electrode in the second direction, and connected to the first B-type conductivity-type semiconductor layer; and
a fourth sub-electrode spaced apart from the second sub-electrode in the second direction, spaced apart from the third sub-electrode in the first direction, and connected to the second B-type conductivity-type semiconductor layer.

19. The light emitting device of claim 18, wherein a separation distance between the first sub-electrode and the second sub-electrode is shorter than a separation distance between the first light emitter and the second light emitter, and
wherein a separation distance between the third sub-electrode and the fourth sub-electrode is shorter than the separation distance between the first light emitter and the second light emitter.

20. The light emitting device of claim 18, further comprising:
an auxiliary element disposed on at least one of the third sub-electrode and the fourth sub-electrode.
